(19) United States
(12) Patent Application Publication
(10) Pub. No.: US 2015/0088440 A1
(43) Pub. Date: Mar. 26, 2015

(54) SOLAR POWER GENERATION MONITORING METHOD AND SOLAR POWER GENERATION MONITORING SYSTEM

(71) Applicant: TOKYO ELECTRON LIMITED, Minato-ku (JP)

(72) Inventors: Jin-Syung CHEN, Hsin-chu (TW); Pei-Chin LIN, Hsin-chu (TW); Osamu NISHIMANIWA, Hsin-chu (TW); Katsushi SUZUKI, Oshu-shi (JP); Lai-Pheng GAN, Hsin-chu (TW); Jui-Kang CHIANG, Hsin-chu (TW); Chin-Yin LEE, Hsin-chu (TW)

(73) Assignee: TOKYO ELECTRON LIMITED, Minato-ku (JP)

(21) Appl. No.: 14/555,844

(22) Filed: Nov. 28, 2014

Related U.S. Application Data
(63) Continuation of application No. PCT/JP2013/003376, filed on May 28, 2013.

(30) Foreign Application Priority Data
May 29, 2012 (JP) 2012-122277

(51) Int. Cl. G01R 21/00

(52) U.S. Cl. CPC G01R 21/006
USPC 702/60

(57) ABSTRACT

A method for monitoring solar power generation includes calculating a cable loss, calculating a maximum power point tracking loss, calculating an inverter loss, calculating a system output coefficient, performing comprehensive calculation based on a rated output power of a solar cell array, a temperature coefficient of the solar cell array, a numerical value of a voltage-current measuring device, a numerical value of a actinometer, a numerical value of a thermometer and a numerical value of a AC power meter such that a module temperature loss is calculated, performing comprehensive calculation based on the cable loss, the maximum power point tracking loss, the inverter loss, the system output coefficient and the module temperature loss such that a module loss is calculated, and displaying and monitoring the cable loss, the maximum power point tracking loss, the inverter loss, the module temperature loss and the module loss.

### CROSS-REFERENCE TO RELATED APPLICATIONS

The present application is a continuation of and claims the benefit of priority to International Application No. PCT/JP2013/003376, filed May 28, 2013, which is based upon and claims the benefit of priority to Japanese Patent Application No. 2012-122277, filed May 29, 2012. The entire contents of these applications are incorporated herein by reference.

### BACKGROUND OF THE INVENTION

1. Field of the Invention

The present invention relates to a solar power generation monitoring method that allows response measures to be performed by instantly monitoring a power generation loss of a solar cell array, and relates to a solar power generation monitoring system that is used for the method.

2. Description of Background Art

In recent years, as earth's resources decrease and eco-consciousness grows, countries are putting efforts on development of alternative energies such as solar energy, wind energy, geothermal energy and hydro-energy, of which power generation using sunlight attracts the most attention. Solar power generation is clean and has advantages such as that it does not cause environmental pollution, that it does not involve resource depletion and that a power generation device can be easily incorporated in a building. Further, along with rapid advancement in semiconductor materials in recent years, sunlight photoelectric conversion efficiency continues to improve and thus, this also resulted in wide application of solar cell modules.

In Taiwan Patent Application No. 98144588, a solar power generation system and a monitoring method thereof are disclosed. The solar power generation system includes a solar cell array that has multiple solar cell modules, a voltage measurement and transmission unit, a wireless signal reception device, and a diagnosis unit. The voltage measurement and transmission unit measures voltages output from the respective solar cell modules, and converts the measured information to wireless signals. The wireless signal reception device receives the wireless signals and converts the wireless signals to transmission information. The diagnosis unit generates analysis information by analyzing the transmission information output from the wireless signal reception device. As a result, in a transmission system of a wireless Internet, an operation status of each of the photoelectric modules is reflected, a defective or inefficient module can be diagnosed and, by performing replacement, that the efficiency of the entire system is reduced due to a broken photoelectric module can be suppressed.

The solar power generation system and the monitoring method thereof that are disclosed in Taiwan Patent Application No. 98144588 can detect an abnormality in power generation of the photoelectric modules. However, as described above, by performing abnormality diagnosis with respect to each of the solar cell modules, it determines whether or not there is an abnormality in a function of each of the solar cell modules and performs replacement with respect to a solar cell module for which there is an abnormality. In Taiwan Patent Application No. 98144588, a judging method with respect to an electronic member or a peripheral hardware is not described. The entire contents of this publication are incorporated herein by reference.

### SUMMARY OF THE INVENTION

According to one aspect of the present invention, a method for monitoring solar power generation includes calculating a cable loss based on difference in numerical values between DC power meters in a solar power generation system including a solar cell array and multiple sensors or based on wire resistance and a numerical value of a DC power meter, calculating a maximum power point tracking loss based on difference in numerical values between the DC power meter and a voltage-current measuring device in the solar power generation system or based on a numerical value of an actinometer and a numerical value of the DC power meter in the solar power generation system, calculating an inverter loss based on difference in numerical values between the DC power meter and an AC power meter, calculating a system output coefficient, performing comprehensive calculation based on a rated output power of the solar cell array, a temperature coefficient of the solar cell array, a numerical value of the voltage-current measuring device, a numerical value of the actinometer, a numerical value of a thermometer and a numerical value of the AC power meter such that a module temperature loss is calculated, performing comprehensive calculation based on the cable loss, the maximum power point tracking loss, the inverter loss, the system output coefficient and the module temperature loss such that a module loss is calculated, and displaying and monitoring the cable loss, the maximum power point tracking loss, the inverter loss, the module temperature loss and the module loss.

According to another aspect of the present invention, a system for monitoring solar power generation includes an information collection device which collects information for calculating a power generation loss, a computing device which is connected to the information collection device and calculates the power generation loss of a solar cell array based on the information for the power generation loss transmitted from the information collection device, and a display and monitoring device which is connected to the computing device, displays and monitors the power generation loss calculated by the computing device. The solar cell array is provided in multiple, each solar cell array has multiple solar cell array units each including multiple solar cell modules positioned in series or in parallel, a DC power output from the solar cell array is converted by an inverter to an AC power, and the computing device calculates a cable loss based on difference in numerical values between DC power meters of the solar cell array or based on wire resistance and a numerical value of a DC power meter, calculates a maximum power point tracking loss based on difference in numerical values between the DC power meter and a voltage-current measuring device in a solar power generation system or based on a numerical value of an actinometer and a numerical value of the DC power meter in the solar power generation system, calculates an inverter loss based on difference in numerical values between the DC power meter and an AC power meter, calculates a system output coefficient, calculates a module temperature loss based on a rated output power of the solar cell array, a temperature coefficient of the solar cell array, a numerical value of the voltage-current measuring device, a numerical value of the actinometer, a numerical value of a thermometer and a numerical value of the AC power meter, and calculates a module loss based on the cable loss, the maximum power point tracking loss, the inverter loss, the system output coefficient and the module temperature loss.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a schematic diagram illustrating a transmission flow of various information for monitoring a power generation loss that is used in a solar power generation monitoring system according to an embodiment of the present invention;

FIG. 2 illustrates a schematic diagram illustrating timing of information update by an instant display monitoring device according to an embodiment of the present invention;

FIG. 3 illustrates a structure diagram illustrating main parts of a solar power generation monitoring system according to an embodiment of the present invention;

FIG. 4 illustrates a graph illustrating monitoring results of cable losses within a certain time interval with respect to different solar cell arrays;

FIG. 5 illustrates a graph illustrating monitoring results of inverter losses within a certain time interval with respect to different solar cell arrays;

FIG. 6 illustrates a graph illustrating measurement results of thermometers within a certain time interval with respect to different solar cell arrays;

FIG. 7 illustrates a graph illustrating analysis results of system output coefficients, cable losses, module temperature losses, inverter losses, maximum power point tracking losses and module losses that are calculated with respect to different solar cell arrays;

FIG. 8 illustrates a graph illustrating measurement results of an actinometer within a certain time interval; and

FIG. 9 illustrates a graph illustrating calculation results of module losses that are calculated within a certain time interval with respect to different solar cell arrays.

### DETAILED DESCRIPTION OF THE EMBODIMENTS

The embodiments will now be described with reference to the accompanying drawings, wherein like reference numerals designate corresponding or identical elements throughout the various drawings.

A solar power generation monitoring method according to an embodiment of the present invention can respectively calculate a cable loss (A), a maximum power point tracking loss (MPPT Loss) (B), an inverter loss (C), a module temperature loss (Temperature Loss) (E) and a system output coefficient (Performance Ratio) (D), which affect a power generation amount of a solar cell array, and further, based on the calculated various power generation losses (A, B, C, E) and the system output coefficient (D), can calculate a module loss (F).

The module loss, broadly speaking, includes losses due to surface contamination, power generation mismatch due to serial or parallel connection of modules, changes in photoelectric conversion efficiency under different solar irradiation conditions, and the like. These losses are highly relevant to a state of a solar cell module and thus are collectively referred to as the module loss here. Therefore, with respect to the calculated module loss (F), an irradiance level correction (G) and an irradiation air mass correction (H) are calculated, and, by correcting the module loss (F), accuracy of the module loss (F) can be improved. An ultimate goal is to monitor a power generation efficiency of a solar cell module on a long-term basis and to provide reference information about whether or not the module has deteriorated. An expression system for the respective losses (A, B, C, F) and corrections (G, H) may be %, W, kWh, kWh/kWp, or other units for instantaneous or cumulative energy.

In a process in which a DC power that is output from a solar cell array is transmitted to an inverter, resistance of a transmission line itself causes a power loss. Therefore, when calculating a power generation loss of solar power generation, a power generation loss due to a power transmission line is also taken in account. The cable loss (A) is a power loss that occurs in a process of power transmission from a solar cell array to an inverter.

An amount of energy convertible by a solar cell module is determined by an irradiation intensity of sunlight and a temperature of the module. For a different operation environment and weather condition, power output of a solar cell module is also different. Therefore, it is necessary to install a maximum power point tracking device and perform monitoring. When the irradiation intensity changes, the maximum power point tracking device can track maximum power point output of the solar cell module and, even when a part of the solar cell module is shielded, can maximize power output of the solar cell module. However, when power decreases due to sunlight being momentarily blocked, there is a possibility that the maximum power point tracking device cannot track the maximum power point. Therefore, a maximum power point tracking loss occurs. The maximum power point tracking loss (B) according to an embodiment of the present invention is a power loss due to that the maximum power point tracking device cannot follow irradiation of sunlight or due to that the power generated by a solar cell array cannot be instantly detected.

The inverter loss (C) is a power loss due to that an inverter converts a DC power to an AC power.

The system output coefficient (D) is a system output coefficient of generated power relative to a rated output power of a solar cell array.

A temperature of a solar cell module rises due to irradiation of sunlight. However, when the temperature of the module rises, a power generation amount decreases. The module temperature loss (E) is a power loss due to a temperature difference between an operating temperature of a solar cell array and a standard temperature of 25° C.

The photoelectric conversion efficiency of a solar cell module changes according to a solar irradiation condition. For example, under a standard test condition (irradiation intensity of 1000 W/m²), in a case where the photoelectric conversion efficiency of a solar cell module is 10%, it means that a solar cell module of an area of 1 m² can output a power of 100 W. However, in practice, in a case where irradiance is low (for example, 200 W/m²), the photoelectric conversion efficiency is reduced (for example, reduced to 9%). In this case, the solar cell module outputs a power of 18 W, not that of a theoretical value of 20 W. The irradiance level correction (G) in the present embodiment is for correcting a power generation loss in a different solar irradiation condition.

When a solar cell module is installed at a different latitude or inclination angle, a sunlight spectrum is also different, and there is a difference as compared to a standard test condition (AM1.5). The AM (Air Mass) is a light intensity distribution at different wavelengths of sunlight. Therefore, in the present embodiment, by calculating the irradiation air mass correction, a power generation loss with respect to a standard solar irradiation condition of AM1.5 at a different sunlight spectrum is corrected.

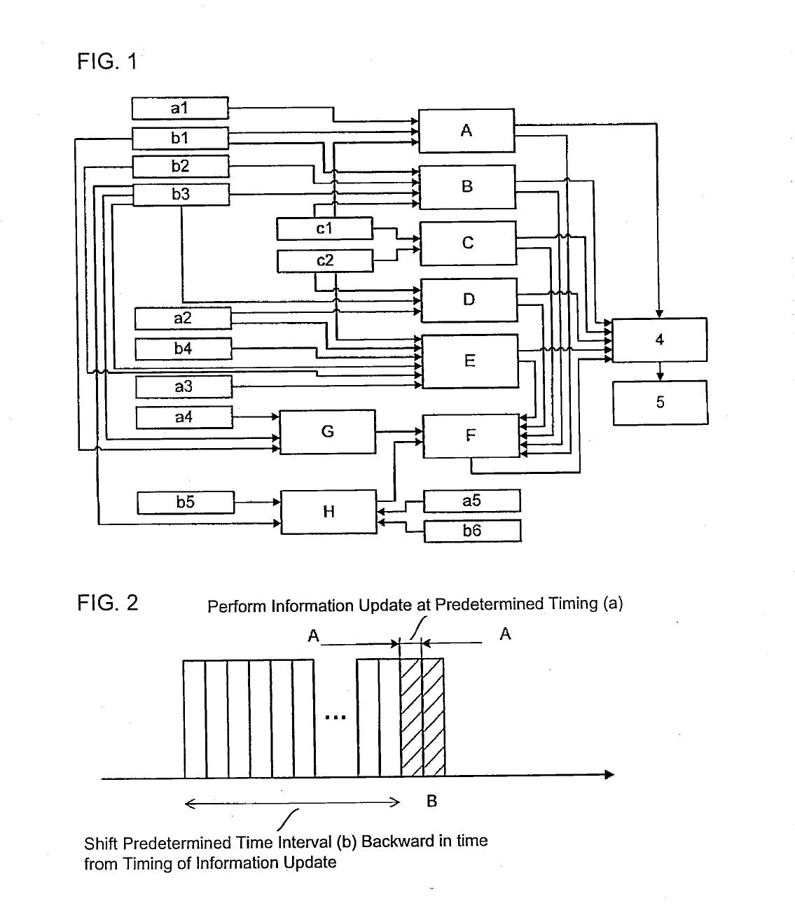

In the following, with reference to FIG. 1, respective calculation methods for the cable loss (A), the maximum power point tracking loss (B), the inverter loss (C), the system output coefficient (D), the module temperature loss (E), the module loss (F), the irradiance level correction (G) and the irradiation air mass correction (H) are described. FIG. 1 illustrates a schematic diagram illustrating transmission flow of various information that is used in a solar power generation monitoring system for calculating and monitoring a power generation loss.

The cable loss (A) is calculated by performing calculation based on a difference between a numerical value (b1) of an array end DC power meter that is provided on a solar cell array end and a numerical number (c1) of an inverter end DC power meter that is provided on an inverter end, or based on a resistance a1 of a DC line for connecting the solar cell array and the inverter and the numerical value (c1) (current value) of the inverter end DC power meter.

The maximum power point tracking loss (B) is calculated by performing calculation based on a difference between the numerical value (b1) of the array end DC power meter and a numerical value (b2) of a voltage-current measuring device for measuring a voltage-current value of the solar cell array, or based on a numerical value (b3) of an actinometer for measuring an intensity of irradiation incident on the solar cell array and the numerical value (c1) (current, voltage, power value) of the inverter end DC power meter.

The inverter loss (C) is calculated based on a difference between the numerical value (c1) of the inverter end DC power meter and a numerical value (c2) of an AC power meter that is provided on an inverter end.

The system output coefficient (D) is calculated from the following Formula 1. In Formula 1, c2 is the numerical value (power generation amount) of the AC power meter; a2 is the rated output power of the solar cell array; b3 is the numerical value of the actinometer for measuring the intensity of irradiation incident on the solar cell array; and 1000 w/m² is a standard irradiance.

D=c2/[a2×(b3/1000 W/m²)] Formula 1:

The module temperature loss (E) is calculated by performing a comprehensive calculation based on the rated output power (a2), a temperature coefficient (a3) of the solar cell array, the numerical value (b2) of the voltage-current measuring device, the numerical value (b3) of the actinometer, a numerical value (b4) of a thermometer for measuring the temperature of the solar cell array and the numerical value (c2) of the AC power meter. Further, instead of the numerical value (c2) of the AC power meter, the module temperature loss (E) may also be calculated based on the numerical value (b1) of the array end DC power meter or the numerical value (c1) of the inverter end DC power meter.

Finally, the module loss (F) is calculated by performing comprehensive calculation based on the calculated cable loss (A), maximum power point tracking loss (B), inverter loss (C), system output coefficient (D) and module temperature loss (E). The calculated module loss can be used for monitoring the power generation efficiency of the solar cell module on a long-term basis and can be used as reference information about whether or not the module has deteriorated.

The irradiance level correction (G) is calculated by performing comprehensive calculation based on an actual photoelectric conversion efficiency (a4) of the module in a different solar irradiation condition, the numerical value (b1) of the array end DC power meter, and the numerical value (b3) of the actinometer.

The irradiation air mass correction (H) is calculated by performing comprehensive calculation based on information (a5) about latitude and an inclination angle of the solar cell array, the numerical value (b3) of a certain actinometer, a numerical value (b5) of another actinometer, and a numerical value (b6) of a spectral photometer. An inclination angle of the certain actinometer is set to be the same as the inclination angle of the solar cell array. The other actinometer is a pyranometer, and an angle between the pyranometer and ground is 0°. The spectral photometer is for measuring light intensity of a sunlight spectrum distribution at different wavelengths.

In the above, the information used in the calculation of the various power generation losses (A, B, C, F) and the corrections (G, H) is transmitted to respective information collectors and is stored. Further, by transmitting the information from the information collectors to a calculation device, the cable loss (A), the maximum power point tracking loss (B), the inverter loss (C), the system output coefficient (D), the module temperature loss (E), the module loss (F), the irradiance level correction (G) and the irradiation air mass correction (H) are calculated by the calculation device.

Thereafter, the cable loss (A), the maximum power point tracking loss (B), the inverter loss (C), the system output coefficient (D), the module temperature loss (E), the module loss (F), the irradiance level correction (G) and the irradiation air mass correction (H) that are calculated by the calculation device are transmitted to an instant display monitoring device (in FIG. 1, illustration of flow of the information that is transmitted to the information collectors and the calculation device is omitted). The information about the numerical values (a1-a5, b1-b6, c1, c2) that are used in the calculation of the various power generation losses (A, B, C, F) and the corrections (G, H) is also transmitted to and stored in the instant display monitoring device. The instant display monitoring device, by performing analysis, instantly performs monitoring with respect to the various power generation losses.

With reference to FIG. 2, timing of information update in the instant display monitoring apparatus is described.

The instant display monitoring device can be set to perform information update at a predetermined timing (a). The predetermined timing (a) may be, for example, daily, weekly or monthly. A frequency of the information update may be set according to timing to monitor the various power generation losses. An information interval of the various power generation losses to be monitored is a time interval obtained by shifting a predetermined time interval (b) backward in time from the timing of information update. The predetermined time interval (b) may be, for example, two weeks, one month or any time interval. An interval sandwiched by two arrows A in FIG. 2 indicates an information update frequency, which may be, for example, daily, weekly or monthly; and an arrow B indicates that a predetermined time interval, for example, two weeks, one month or any time interval is shifted backward in time.

A reason for shifting a predetermined time interval backward in time from the timing of information update is that, when only the power generation loss at the timing when monitoring is performed is monitored, since a power generation condition of a solar cell module may be affected by a weather condition, there is a risk that a power generation amount at the timing when monitoring is performed greatly varies and thus analysis information may be unsuitable as reference information. Therefore, by selecting a predetermined time interval, by performing comparison with respect to relevant hardwares (such as an inverter, a power transmission circuit, or sensors (such as an actinometer, a spectral photometer, a thermometer, a voltammeter, and a power meter)) between solar cell arrays, whether or not there is an abnormality in a function of a hardware can be determined, or an abnormality can be discovered. By confirming an operation status of an information collection software via organizing and analyzing various instantaneous information, its accuracy can be confirmed and thus an abnormality can be discovered.

In the following, a process flow of judging whether or not there is an abnormality in the relevant hardware or the information collection software of the solar power generation system is sequentially described for each of the system output coefficient, the cable loss, the module temperature loss, the inverter loss, the maximum power point tracking loss, and the module loss.

### (1) System Output Coefficient

Based on system output coefficients that are calculated from the above-described Formula 1 with respect to different solar cell arrays, whether or not there is an abnormal value is confirmed. When there is an abnormal value, whether or not there is an abnormality in power generation amounts of the different solar cell arrays is determined by comparison.

The judgment comparison regarding whether or not there is an abnormality in the power generation amounts of the different solar cell arrays is performed by comparing the power generation amounts, irradiances and module temperatures of the different solar cell arrays. For example, a higher irradiance indicates more sunlight is absorbed, so the power generation amount should also be higher. However, at certain timing, when the irradiances of the solar cell arrays are substantially the same, but the power generation amount of only one solar cell array is low, it indicates that an abnormality has occurred in the power generation amount of that one solar cell array. The module temperature and the power generation amount have an inverse relation. For a higher module temperature, the power generation amount is lower. Whether or not an abnormality has occurred in the power generation amount of a solar cell array can also be determined by comparing the power generation amount and the module temperature.

When there is an abnormality in the power generation amount, whether or not there is an abnormality in a function of an AC power meter is further confirmed. In this case, a setting value or a parameter or the like of the AC power meter is confirmed. When there is no abnormality in the function of the AC power meter, whether or not there is an abnormality in a function of an actinometer is further confirmed. When both the functions of the AC power meter and the actinometer are all normal, but there is an abnormal value for the power generation amount of a certain solar cell array, it is conceivable that an abnormality has occurred in a function of the information collection software. Therefore, confirmation with respect to the information collection software is performed. When there is also no abnormality in the function of the information collection software, there is a possibility that the power generation amount is reduced due to deterioration of the solar cell module or other factors. For example, it is presumable that there is a possibility that the power generation amount is reduced due to surface contamination of the solar cell module.

As a result, whether or not there is an abnormality in the relevant hardware (such as the AC power meter and the actinometer) or the information collection software of the solar power generation system can be determined, its accuracy can be confirmed, and thus a source causing the abnormality can be discovered, and whether or not deterioration has occurred in the solar cell module can be determined.

### (2) Cable Loss

Whether or not there is an abnormal value in cable losses that are calculated with respect to different solar cell arrays is confirmed. When there is an abnormal value, current values that are measured with respect to the different solar cell arrays are compared.

In this case, the judgment comparison regarding whether or not there is an abnormality in the current values that are measured with respect to the different solar cell arrays is performed as described above by comparing the power generation amounts, irradiances and module temperatures of the different solar cell arrays. For example, for a higher irradiance, a value of an output current should also be higher.

When there is an abnormality in the current values of the power meters, first, whether or not a resistance value is increased and a current value is reduced due to deterioration of a line is confirmed. When the line is normal, whether or not there is an abnormality in functions of the power meters is confirmed. In this case, a setting value or a parameter or the like of the power meter is confirmed. When the functions of the power meters are all normal, but there is an abnormality in the power generation amount of a certain solar cell array, it is conceivable that an abnormality has occurred in a function of the information collection software. Therefore, confirmation with respect to the information collection software is performed. When there is no abnormality in the function of the information collection software, there is a possibility that the power generation amount is reduced due to deterioration of the solar cell module or other factors. For example, it is presumable that there is a possibility that the power generation amount is reduced due to surface contamination of the solar cell module.

As a result, whether or not there is an abnormality in the line, the relevant hardware or the information collection software of the solar power generation system can be determined, its accuracy can be confirmed, or an abnormality can be discovered, and whether or not deterioration has occurred in the solar cell module can be determined.

### (3) Module Temperature Loss

Whether or not there is an abnormal value in module temperature losses that are calculated with respect to different solar cell arrays is confirmed. When there is an abnormal value, module temperatures that are measured with respect to the different solar cell arrays are compared.

In this case, whether or not there is an abnormality in the module temperatures that are measured with respect to different solar cell arrays is determined as described above by comparing the power generation amounts, irradiances and module temperatures of the different solar cell arrays. For example, for a higher irradiance, a module temperature should also be higher. However, at certain timing, when the irradiances of the solar cell arrays are substantially the same, but the temperature of only one solar cell array is high or low, it indicates that an abnormality has occurred in the temperature of that one solar cell array.

Also by confirming installation locations, installation conditions or operating environments of the respective solar cell arrays, that a difference has occurred in the measured temperatures of the solar cell arrays due to the installation location of a certain solar cell array, that there is an abnormality in the installation conditions of the solar cell arrays, or that an abnormality has occurred in the temperatures of the solar cell arrays due to a weather condition at the time, can be determined.

When there is no abnormality in the installation conditions or the operating environments of the solar cell arrays but there is an abnormality in the temperatures of the solar cell arrays, whether or not there is an abnormality in a function of a thermometer for measuring a temperature of a solar cell array is further confirmed. When the function of the thermometer is normal, there is a possibility that there is an abnormality in a function of the information collection software. Therefore, confirmation with respect to the information collection software is performed.

As a result, whether or not there is an abnormality in the installation condition, the relevant hardware (thermometer) or the function of the information collection software of the solar power generation system can be determined, its accuracy can be confirmed, or an abnormality can be discovered.

### (4) Inverter Loss

Whether or not there is an abnormal value in inverter losses that are calculated with respect to different solar cell arrays is confirmed. When there is an abnormal value, numerical values of the inverter end DC power meters and AC power meters of the different solar cell arrays are compared.

When there is an abnormal value in the numerical values of the power meters, whether or not there is an abnormality in a function of an inverter is confirmed. When there is no abnormality in the function of the inverter, whether or not there is an abnormality in a function of the power meters is further confirmed. When the function of the power meters is all normal, there is a possibility that there is an abnormality in a function of the information collection software. Therefore, confirmation with respect to the information collection software is performed.

As a result, whether or not there is an abnormality in the inverter, the relevant hardware (inverter end DC power meter and AC power meter) or the function of the information collection software of the solar power generation system can be determined, its accuracy can be confirmed, or an abnormality can be discovered.

### (5) Maximum Power Point Tracking Loss

Whether or not there is an abnormal value in maximum power point tracking losses that are calculated with respect to different solar cell arrays is confirmed. When there is an abnormal value, whether or not there is an abnormality in the maximum power point tracking device is confirmed. When there is no abnormality, whether or not there is an abnormality in a solar irradiation condition is further confirmed (for example, it is not possible to track the maximum power point due to being covered by clouds).

The calculation of the maximum power point tracking loss is performed by obtaining a linear regression relation between the current and the irradiance by performing a regression analysis, which is a statistical method. In order to obtain the linear regression relation, it is necessary to remove outliers. However, a setting value of a parameter for removing the outliers affects the accuracy of the calculated maximum power point tracking loss. Therefore, when the solar irradiation condition is normal, whether or not it is necessary to perform correction with respect to the parameter that is used in the calculation of the maximum power point tracking loss is further confirmed.

When it is confirmed that it is not necessary to perform correction with respect to the parameter that is used in the calculation of the maximum power point tracking loss, there is a possibility that there is an abnormality in a function of the information collection software. Therefore, confirmation with respect to the information collection software is performed.

As a result, whether or not there is an abnormality in the maximum power point tracking device or the function of the information collection software can be determined, its accuracy can be confirmed, or an abnormality can be discovered.

### (6) Module Loss

Whether or not there is an abnormal value in module losses that are calculated with respect to different solar cell arrays is confirmed. In a case where there is an abnormal value in the module losses but there is no abnormal value in any of the above-calculated system output coefficients, cable losses, module temperature losses, inverter losses and maximum power point tracking losses, confirmation with respect to the information collection software is performed.

As a result, whether or not there is an abnormality in the information collection software can be determined, its accuracy can be confirmed, or an abnormality can be discovered.

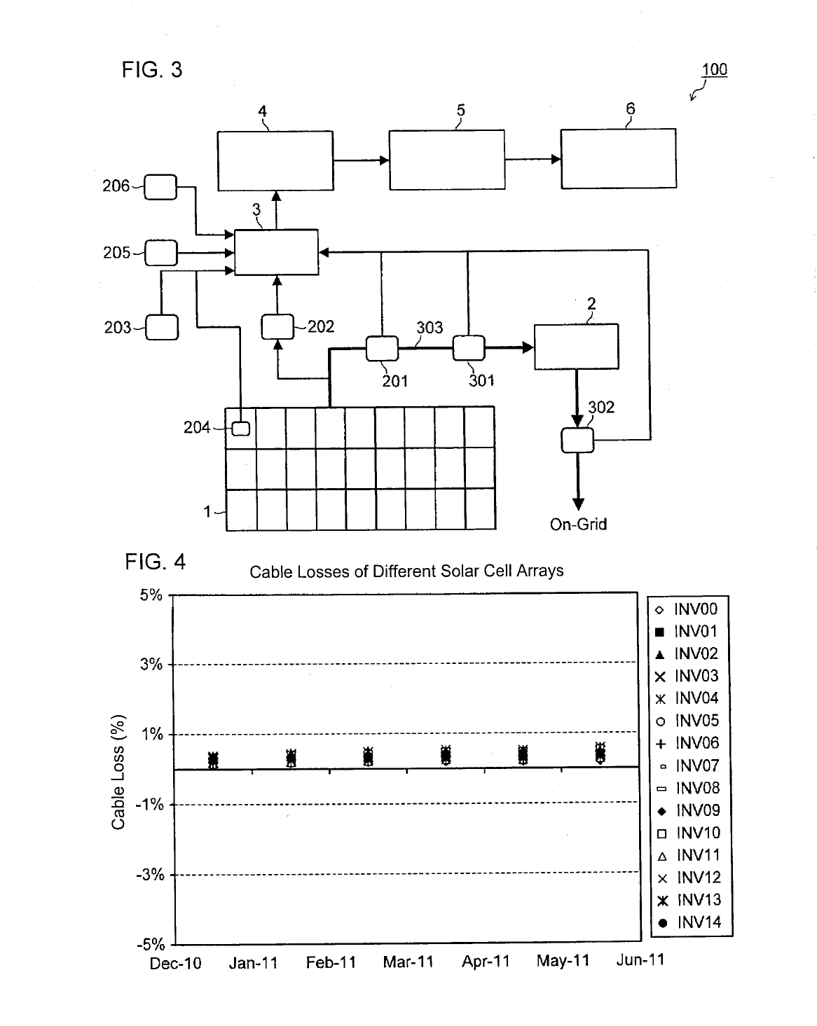

With reference to FIG. 3, a solar power generation monitoring system that uses the above-described monitoring method is described. FIG. 3 illustrates a configuration diagram illustrating a solar power generation monitoring system 100 according to an embodiment of the present invention.

As illustrated in FIG. 3, the solar power generation monitoring system 100 according to an embodiment of the present invention includes multiple solar cell arrays 1 that convert sunlight energy to electrical energy, an inverter 2 that converts a DC power that is output by the solar cell arrays 1 to an AC power, an information collector 3 for collecting information that is used in calculation of various power generation losses in the solar power generation monitoring system 100, a calculation device 4 for calculating the power generation losses of the solar cell arrays 1, an instant display monitoring device 5 that instantly performs monitoring with respect to the various power generation losses that are calculated by the calculation device 4, and an alarm and advice device 6 that issues an alarm and an advice based on monitoring results that are displayed in the instant display monitoring device 5.

The solar cell arrays 1 are configured in such a manner that multiple solar cell array units are each structured by arranging and assembling multiple solar cell modules in series or in parallel, and further multiple solar cell arrays 1 are each structured from multiple solar cell array units (in FIG. 3, for convenience of illustration, only one solar cell array is illustrated). A DC power meter 201, a voltage-current measuring device 202, an actinometer 203, a thermometer 204, an actinometer 205 and a spectral photometer 206 are connected to the solar cell array 1.

The DC power meter 201 is a DC clamp meter that is provided on a solar cell array end, and numerical values displayed thereon include a voltage (V), a current (A), and a power (W or kWh). In the following, in order to distinguish the DC power meter 201 from an inverter end DC power meter, the DC power meter 201 may be referred to as an “array end DC power meter.” The voltage-current measuring device 202 is a sensor for measuring a voltage-current characteristic curve of the solar cell array 1. The actinometer 203 is a sensor for measuring an intensity of irradiation incident on the solar cell array 1, and an inclination angle of the actinometer 203 is set to be the same as an inclination angle of the solar cell array 1. The thermometer 204 is a sensor for measuring a temperature of the solar cell array 1. The actinometer 205 is a pyranometer, and is a sensor for measuring an intensity of irradiation incident on a horizontal surface, and an angle between the actinometer 205 and the ground is 0°. The spectral photometer 206 is for measuring a spectral distribution (spectral density) by detecting an intensity of sunlight.

The inverter 2 is for converting a DC power that is output by the solar cell array 1 to an AC power, and functions as a maximum power point tracking device. A DC power meter 301 and an AC power meter 302 are connected to the inverter 2.

The DC power meter 301 is a DC clamp meter that is provided on an inverter DC end, and numerical values displayed thereon include a voltage (V), a current (A), and a power (W or kWh). In the following, in order to distinguish the DC power meter 301 from an array end DC power meter, the DC power meter 301 may be referred to as an “inverter end DC power meter.” The AC power meter 302 is an AC clamp meter that is provided on an inverter AC end, and numerical values displayed thereon include a voltage V, a current A, and a power (W or kWh).

The solar cell array 1 and the array end DC power meter 201, the array end DC power meter 201 and the inverter end DC power meter 301, and, the inverter end DC power meter 301 and the inverter 2, are connected by a line 303.

The information collector 3 collects information that is used in the calculation of the various power generation losses in the solar power generation monitoring system, and the collected various information is further transmitted to the calculation device 4.

In the present embodiment, by having the information collector 3, the solar power generation monitoring system 100 can respond to requests from different users. For example, when the solar power generation monitoring system 100 is sold to different users, the solar power generation monitoring system 100 can be connected to electronic members (such as a power meter and a voltammeter) or sensors (such as an actinometer, a spectral photometer, a thermometer and a voltammeter) that are provided in a solar power generation system that a user already has; or electronic members (such as a power meter, and a voltammeter) or sensors (such as an actinometer, a thermometer and a voltammeter) that are provided in the solar power generation monitoring system 100 may also be used.

As illustrated in FIG. 3, to the information collector 3, the numerical value (b1) of the array end DC power meter 201, the numerical value (b2) of the voltage-current measuring device 202, the numerical value (b3) of the actinometer 203, the numerical value (b4) of the thermometer 204, the numerical value (b5) of the actinometer 205, the numerical value (b6) of the spectral photometer 206, and the numerical value (c1) of the inverter end DC power meter 301 and the numerical value (c2) of the AC power meter 302 are transmitted, and further, for example, the resistance (a1) of the line 303, the rated output power (a2) and the temperature coefficient (a3) are also transmitted.

The line resistance (a1) may be a resistance value inferred according to a length of the line 303, or an actually measured resistance value. The rated output power (a2) is the rated output power of the solar cell array 1. The temperature coefficient (a3) is the temperature coefficient of the solar cell array 1.

The calculation device 4 is connected to the information collector 3. In the calculation device 4, the cable loss (A), the maximum power point tracking loss (B), the inverter loss (C), the module temperature loss (E) and the system output coefficient (D), which affect the power generation amount of the solar cell array 1, are respectively calculated; and further, based on the calculated various power generation losses (A, B, C, E) and the system output coefficient (D), the module loss (F) is calculated.

With respect to the calculated module loss (F), the calculation device 4 can calculate the irradiance level correction (G) and the irradiation air mass correction (H) and, by correcting the module loss (F), can improve the accuracy of the module loss (F).

The instant display monitoring device 5 is connected to the calculation device 4. The cable loss (A), the maximum power point tracking loss (B), the inverter loss (C), the system output coefficient (D), the module temperature loss (E), the module loss (F), the irradiance level correction (G) and the irradiation air mass correction (H), which are calculated by the calculation device 4, are respectively transmitted to and stored in the instant display monitoring device 5. The information about the numerical values (a1-a5, b1-b6, c1, c2) that are used in the calculation of the various power generation losses is also transmitted to and stored in the instant display monitoring device 5, and the instant display monitoring device 5 instantly performs monitoring with respect to the various power generation losses.

The monitoring results are transmitted to the alarm and advice device 6. Based on the monitoring results displayed on the instant display monitoring device 5, the alarm and advice device 6 issues an alarm and an advice.

An example of the monitoring results that are displayed on the instant display monitoring device 5 is described.

FIG. 4 illustrates a graph illustrating monitoring results of the cable losses within a certain time interval with respect to different solar cell arrays; a horizontal axis represents the time interval in which the monitoring is performed, and a vertical axis represents the cable losses. According to FIG. 4, it is found that there is no abnormality in the cable losses of all the solar cell arrays within the time interval in which the monitoring is performed.

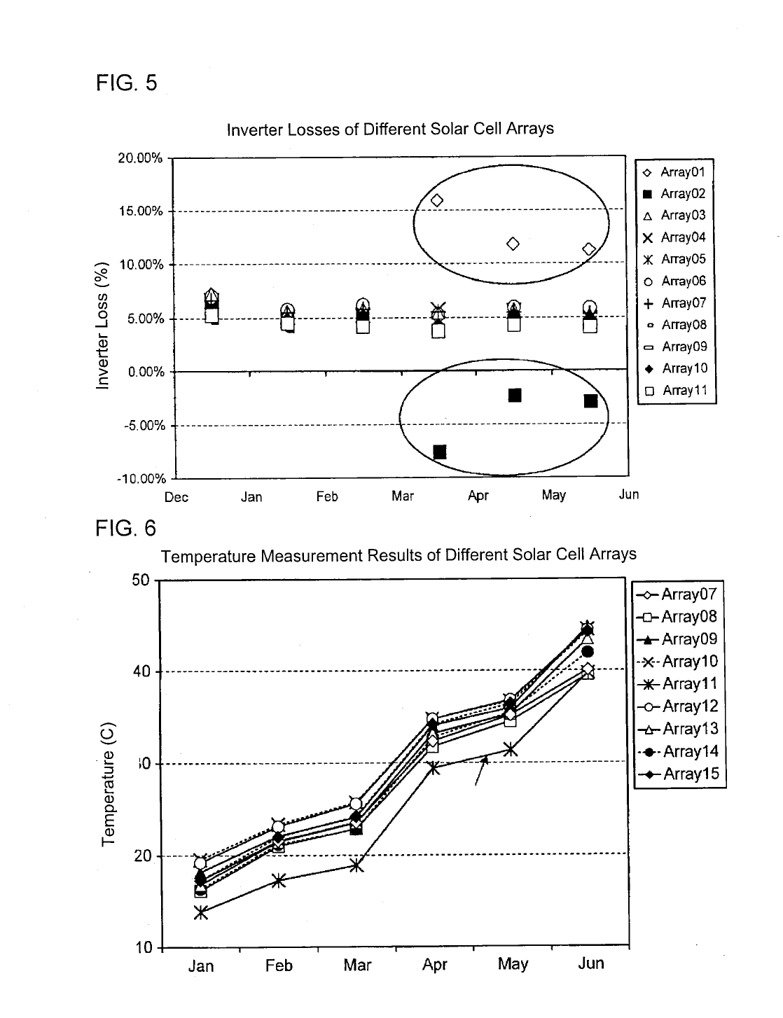

FIG. 5 illustrates a graph illustrating monitoring results of the inverter losses within a certain time interval with respect to different solar cell arrays; a horizontal axis represents the time interval in which the monitoring is performed, and a vertical axis represents the inverter losses. According to FIG. 5, it is found that there are abnormalities for a solar cell array (Array01) and a solar cell array (Array02) from April to June.

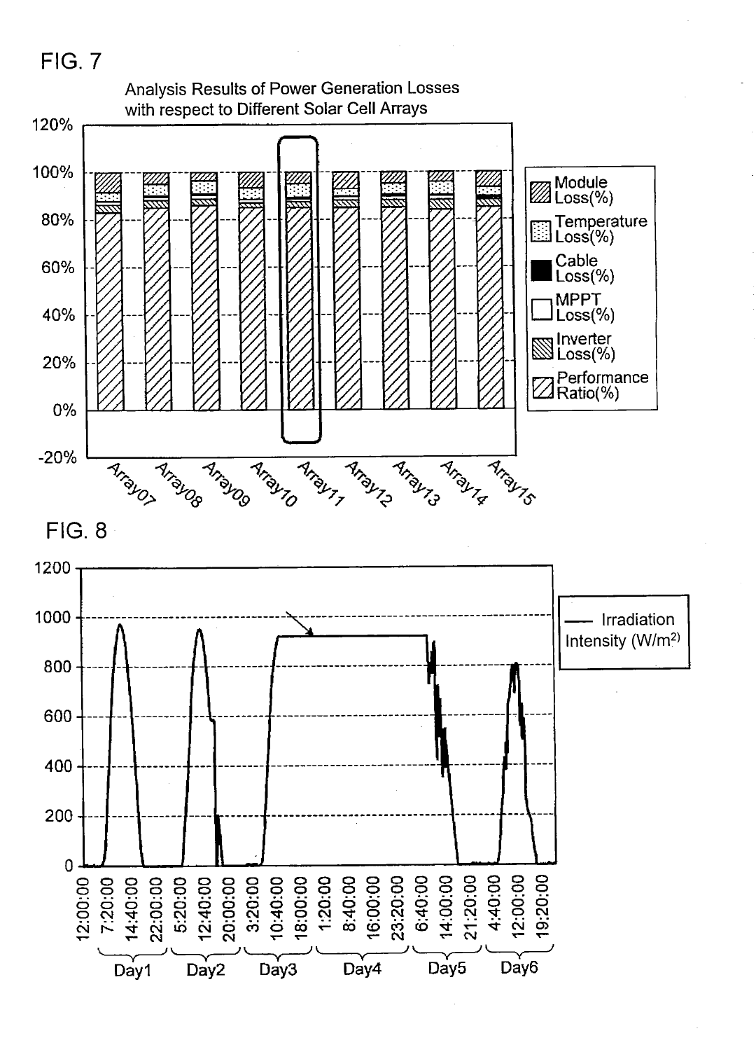

FIG. 6 illustrates a graph illustrating measurement results of thermometers within a certain time interval with respect to different solar cell arrays; a horizontal axis represents the time interval in which the monitoring is performed, and a vertical axis represents the temperatures of the thermometers. FIG. 7 illustrates a graph illustrating analysis results of system output coefficients, cable losses, module temperature losses, inverter losses, maximum power point tracking losses and module losses that are calculated with respect to different solar cell arrays; A horizontal axis represents solar cell arrays, and a vertical axis represents percentages of the various power generation losses and the system output coefficients.

According to FIG. 6, it is found that there is an abnormality in the measurement results of the module temperature of a certain solar cell array (Array11). However, comparing the solar cell array (Array11) in FIG. 7 with solar cell arrays (Array12), (Array13), (Array14) that are installed at the same place (for example, solar cell arrays that are similarly installed on a periphery or at a center), an abnormality is not found in the calculation results of the module temperature loss. Therefore, it can be inferred that there is an abnormality in a certain thermometer (the thermometer for measuring the temperature of the solar cell array (Array11)).

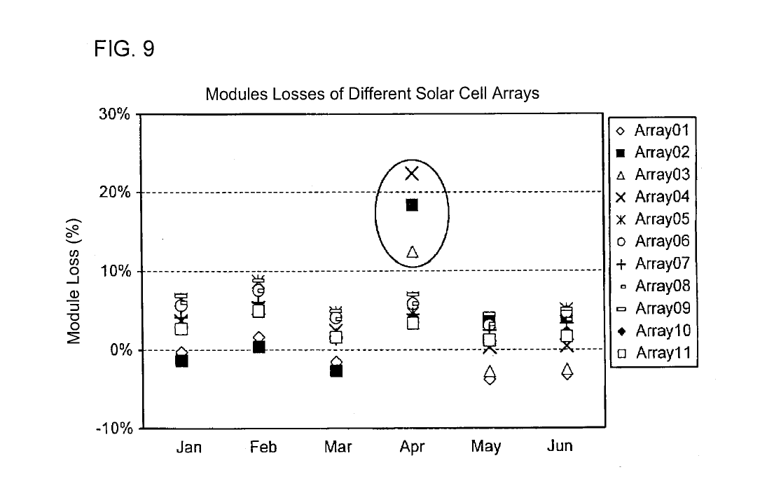

FIG. 8 illustrates a graph illustrating measurement results of an actinometer within a certain time interval; a horizontal axis represents the time interval in which the monitoring is performed, and a vertical axis represents the measurement results of the actinometer.

As illustrated in FIG. 8, it is found that there is an abnormality in the measurement results of irradiance in a time period from Day3 to Day5. There is no incidence of sunlight at night. Therefore, the irradiance at night during that time period should be zero. However, the measurement results for the irradiance are numerical values similar to measurement results during daytime. Therefore, it is inferred that an abnormality has occurred in the information collection software.

The instant display monitoring device can monitor the power generation efficiency of a solar cell module that is installed in a solar power generation system and can detect an abnormality. Via instant calculation of the module loss, monitoring can be performed with respect to actual power generation efficiency of a solar cell module that is installed in a solar power generation system, whether or not deterioration has occurred in the solar cell module can be confirmed.

For example, FIG. 9 illustrates a graph illustrating calculation results of module losses that are calculated within a predetermined time interval with respect to different solar cell arrays; a horizontal axis represents the time interval in which the monitoring is performed, and a vertical axis represents the module losses. From FIG. 9, it is found that there are abnormalities in the module losses of solar cell arrays (Array02), (Array03), (Array04) in April.

The graphs of FIG. 4-9 are actual monitoring screens that are displayed on the instant display monitoring device. These monitoring results are transmitted to the alarm and advice device. Based on the monitoring results that are displayed on the instant display monitoring device, the alarm and advice device issues an alarm and an advice.

A solar power generation system obtains an optimal output power in such a manner that solar cell modules (solar panels) are each structured by arranging and assembling solar cells in series or in parallel; then, a rated output power of each of the solar cell modules, an inclination angle of the device, and a range of a voltage output from an inverter or a power conditioner that has a maximum power point tracking (MPPT) function, are determined; and finally, a preferred solar cell array is structured by arranging the solar cell modules in series or in parallel.

Power generation efficiency of solar power generation is affected by an installation location of a power plant (such as a latitude of the power plant, whether it is located on a mountain or a flatland), a climate condition (such as solar irradiation, temperature, and a weather condition), or an inclination angle and an azimuthal angle of a solar cell module. An electronic member (such as an inverter or a power transmission line) in a solar power generation system, or a peripheral hardware (such as an actinometer, a thermometer, and a voltammeter) of the solar power generation system, also affects the power generation efficiency. Therefore, a system is desired that can monitor the power generation efficiency of a solar power plant, can clearly identify factors that affect the solar power generation efficiency, and can perform response measures.

However, other electronic members (such as an inverter or a power transmission line) of a solar power generation system or peripheral hardware (such as an actinometer, a thermometer and a voltammeter) of the solar power generation system, also cannot affect judging of the power generation efficiency. So far there is no method that can clearly identify factors that affect the power generation efficiency of a solar power generation system.

In a large-sized solar power generation system, power generation efficiency of a system is evaluated via a usual PR value (PR: performance ratio; system output coefficient). The PR value is an indicator that evaluates the power generation efficiency of a system, and is a percentage of energy absorbed from sunlight that is converted by a module to a power generation amount. The higher the numerical value of the PR value is, the better the efficiency is, indicating that the solar power generation system can convert more energy of sunlight into electrical energy. However, by the PR value only, an actual operation status of a solar power generation system cannot be accurately evaluated. Therefore, without performing a comprehensive evaluation with respect to the PR value and various factors of power generation losses, maintenance and operational management with respect to the solar power generation system cannot be accurately performed.

A solar power generation monitoring method according to an embodiment of the present invention, by performing a comparison with respect to relevant hardwares such as inverters, power transmission circuits, or sensors (such as an actinometer, a thermometer, a voltammeter and a power meter) of different solar cell arrays, can determine an operation status thereof, and thus can discover an abnormality. By confirming an operation status of a software for collecting information via organizing and analyzing various instantaneous information, its accuracy can be confirmed or an abnormality can be discovered.

A solar power generation monitoring system according to an embodiment of the present invention can monitor the power generation efficiency of a solar cell module that is used in a solar power generation system, and can detect an abnormality thereof. By monitoring actual power generation efficiency with respect to a solar cell module that is used in a solar power generation system via instant calculation of a power generation loss of the solar cell module, whether or not deterioration in efficacy has occurred can be confirmed.

A first aspect of the present invention is a solar power generation monitoring method that monitors various power generation losses in a solar power generation system that is structured by a solar cell array and sensors, and detects an abnormality. The solar power generation monitoring method includes: a step of calculating a cable loss by performing calculation based on a numerical difference between different DC power meters in the solar power generation system, or based on a resistance or a wire and a numerical value of a DC power meter; a step of calculating a maximum power point tracking loss by performing calculation based on a numerical difference between a DC power meter and a voltage-current measuring device in the solar power generation system, or based on a numerical value of an actinometer and a numerical value of a DC power meter in the solar power generation system; a step of calculating an inverter loss based on a numerical difference between a DC power meter and an AC power meter; a step of calculating a system output coefficient; a step of calculating a module temperature loss by performing comprehensive calculation based on a rated output power of the solar cell array, a temperature coefficient of the solar cell array, a numerical value of the voltage-current measuring device, a numerical value of the actinometer, a numerical value of a thermometer and a numerical value of the AC power meter; a step of calculating a module loss by performing comprehensive calculation based on the cable loss, the maximum power point tracking loss, the inverter loss, the system output coefficient and the module temperature loss that are calculated in the above steps; and a step of displaying and monitoring the cable loss, the maximum power point tracking loss, the inverter loss, the module temperature loss and the module loss that are calculated in the above steps.

A second aspect of the present invention is a solar power generation monitoring system that monitors power generation losses of a solar power generation system by using the solar power generation monitoring method of the above-described first aspect. The solar power generation monitoring system includes: multiple solar cell arrays that are structured in such a manner that solar cell array units are each structured by arranging and assembling multiple solar cell modules in series or in parallel, and then the solar cell arrays are structured from the solar cell array units; an inverter that converts a DC power that is output from the solar cell arrays to an AC power; an information collector for collecting information that is used in calculation of various power generation losses in the solar power generation monitoring system; a calculation device that is connected to the information collector and, based on the information of the various power generation losses that is transmitted from the information collector, calculates the various power generation losses of the solar cell arrays; a display and monitoring device that is connected to the calculation device and displays and monitors the various power generation losses that are calculated by the calculation device; and an alarm and advice device that is connected to the display and monitoring device and, based monitoring results of the various power generation losses that are displayed on the display and monitoring device, issues an alarm and an advice.

A solar power generation monitoring method and the system thereof according to an embodiment of the present invention can monitor various power generation losses in a solar power generation system and detect an abnormality.

Obviously, numerous modifications and variations of the present invention are possible in light of the above teachings. It is therefore to be understood that within the scope of the appended claims, the invention may be practiced otherwise than as specifically described herein.

1. A method for monitoring solar power generation, comprising:
calculating a cable loss based on difference in numerical values between DC power meters in a solar power generation system comprising a solar cell array and a plurality of sensors or based on wire resistance and a numerical value of a DC power meter;
calculating a maximum power point tracking loss based on difference in numerical values between the DC power meter and a voltage-current measuring device in the solar power generation system or based on a numerical value of an actinometer and a numerical value of the DC power meter in the solar power generation system;
calculating an inverter loss based on difference in numerical values between the DC power meter and an AC power meter;
calculating a system output coefficient;
performing comprehensive calculation based on a rated output power of the solar cell array, a temperature coefficient of the solar cell array, a numerical value of the voltage-current measuring device, a numerical value of the actinometer, a numerical value of a thermometer and a numerical value of the AC power meter such that a module temperature loss is calculated;
performing comprehensive calculation based on the cable loss, the maximum power point tracking loss, the inverter loss, the system output coefficient and the module temperature loss such that a module loss is calculated; and
displaying and monitoring the cable loss, the maximum power point tracking loss, the inverter loss, the module temperature loss and the module loss.

2. A method for monitoring solar power generation according to claim 1, wherein the calculating of the cable loss comprises calculating the cable loss based difference in numerical values between an array end DC power meter provided on a solar cell array end and an inverter end DC power meter provided on an inverter end or based on wire resistance of a DC line connecting the solar cell array and the inverter and a numerical value of the inverter end DC power meter.

3. A method for monitoring solar power generation according to claim 1, wherein the calculating of the maximum power point tracking loss comprises calculating the maximum power point tracking loss based on difference in numerical values between the DC power meter which is an inverter end DC power meter provided on an inverter end and the voltage-current measuring device which is configured to measure a voltage-current value of the solar cell array.

4. A method for monitoring solar power generation according to claim 1, wherein the calculating of the inverter loss comprises calculating the inverter loss based on difference in numerical values between the DC power meter which is an inverter end DC power meter provided on an inverter end and the AC power meter which is provided on the inverter end.

5. A method for monitoring solar power generation according to claim 1, wherein the calculating of the system output coefficient comprises calculating the system output coefficient from D=c2/[a2×(b3/1000 W/m²)], where D represents the system output coefficient, c2 represents a numerical value of the AC power meter provided on an inverter end, a2 represents the rated output power of the solar cell array, b3 represents a numerical value of the actinometer configured to measure intensity of solar irradiation incident on the solar cell array, and 1000 w/m² represents a standard solar irradiance.

6. A method for monitoring solar power generation according to claim 1, wherein the performing of comprehensive calculation for the module temperature loss comprises performing the comprehensive calculation based on a voltage-current value of the voltage-current measuring device configured to measure the voltage-current value of the solar cell array, a numerical value of the actinometer configured to measure intensity of solar irradiation incident on the solar cell array, a numerical value of the thermometer configured to measure a temperature of the solar cell array, and a numerical value of the AC power meter provided on an inverter end.

7. A method for monitoring solar power generation according to claim 1, further comprising:
issuing at least one of an alarm and an advice based on a monitoring result obtained from the displaying of the cable loss, the maximum power point tracking loss, the inverter loss, the module temperature loss and the module loss.

8. A method for monitoring solar power generation according to claim 1, wherein the displaying of the cable loss, the maximum power point tracking loss, the inverter loss, the module temperature loss and the module loss includes updating the cable loss, the maximum power point tracking loss, the inverter loss, the module temperature loss and the module loss at predetermined timing, and the monitoring of the cable loss, the maximum power point tracking loss, the inverter loss, the module temperature loss and the module loss includes shifting information interval of the cable loss, the maximum power point tracking loss, the inverter loss, the module temperature loss and the module loss backward in time from a predetermined time interval.

9. A method for monitoring solar power generation according to claim 5, wherein the calculating of the system output coefficient includes confirming whether an abnormal value is present in system output coefficients calculated from D=c2/[a2×(b3/1000 W/m²)] with respect to different solar cell arrays, comparing power generation amounts with respect to different solar cell arrays for abnormality, confirming whether abnormality exists in function of the AC power meter, confirming whether abnormality exists function of the actinometer, and confirming whether abnormality exists in function of an information collection software which collects information for calculating different types of power generation losses in the solar power generation system.

10. A method for monitoring solar power generation according to claim 5, wherein the comprehensive calculation for the module temperature loss comprises confirming whether an abnormal value is present in module temperature losses calculated with respect to different solar cell arrays, comparing module temperatures measured with respect to different solar cell arrays for abnormality, confirming whether abnormality exists in installation condition and operating environment of each solar cell array, confirming whether abnormality exists in function of the thermometer configured to measure temperature of the solar cell array, and confirming whether abnormality exists in function of an information collection software which collects information for calculating different types of power generation losses in the solar power generation system.

11. A method for monitoring solar power generation according to claim 4, wherein the calculating of the inverter loss comprises confirming whether an abnormal value is present in inverter losses calculated with respect to different solar cell arrays, comparing numerical values of inverter end DC power meters and AC power meters with respect to different solar cell arrays for abnormality, confirming whether abnormality exists in function of inverter end DC power meters and AC power meters with respect to different solar cell arrays, and confirming whether abnormality exists in function of an information collection software which collects information for calculating different types of power generation losses in the solar power generation system.

12. A method for monitoring solar power generation according to claim 3, wherein the calculating of the maximum power point tracking loss comprises confirming whether an abnormal value is present in maximum power point tracking losses calculated with respect to different solar cell arrays, confirming whether abnormality is found in solar irradiation condition, confirming whether correction is necessary with respect to parameters for the calculating of the maximum power point tracking loss, and confirming whether abnormality exists in function of an information collection software which collects information for calculating different types of power generation losses in the solar power generation system.

13. A method for monitoring solar power generation according to claim 3, wherein the comprehensive calculation for the module loss comprises confirming whether an abnormal value is present in module losses with respect to different solar cell arrays, confirming whether an abnormal value is present in the system output coefficient, the cable loss, the module temperature loss, the inverter loss, and the maximum power point tracking loss, and confirming whether abnormality exists in function of an information collection software which collects information for calculating different types of power generation losses in the solar power generation system.

14. A method for monitoring solar power generation according to claim 1, further comprising:
performing comprehensive calculation based on an actual photoelectric conversion efficiency of the solar cell array in a different solar irradiation condition, the numerical value of the array end DC power meter, and the numerical value of the actinometer such that an irradiance level correction value is calculated;
performing comprehensive calculation based on the numerical value of the actinometer, a numerical value of another actinometer, information for a latitude and an inclination angle of the solar cell array, and a numerical value of a spectral photometer such that an irradiation air mass correction value is calculated;
correcting the module loss based on the irradiance level correction value and the irradiation air mass correction value; and
setting an inclination angle of the actinometer to be same as the inclination angle of the solar cell array,
wherein the other actinometer is a pyranometer positioned at an angle horizontal with respect to ground, and the spectral photometer is connected to the solar cell array and configured to detect intensity of sunlight and measure spectrum distribution.

15. A method for monitoring solar power generation according to claim 1, wherein the cable loss, the maximum power point tracking loss, the inverter loss, and the module temperature loss are displayed in %, W, kWh and kWh/kWp or other units for instantaneous or cumulative energy.

16. A system for monitoring solar power generation, comprising:
an information collection device configured to collect information for calculating a power generation loss;
a computing device connected to the information collection device and configured to calculate the power generation loss of a solar cell array based on the information for the power generation loss transmitted from the information collection device;
a display and monitoring device connected to the computing device and configured to display and monitor the power generation loss calculated by the computing device; and
an alarm and advice device connected to the display and monitoring device,
wherein the solar cell array is provided in a plurality, each solar cell array comprises a plurality of solar cell array units each comprising a plurality of solar cell modules positioned in series or in parallel, a DC power output from the solar cell array is converted by an inverter to an AC power, the computing device is configured to calculate a cable loss based on difference in numerical values between DC power meters of the solar cell array or based on wire resistance and a numerical value of a DC power meter, calculate a maximum power point tracking loss based on difference in numerical values between the DC power meter and a voltage-current measuring device in a solar power generation system or based on a numerical value of an actinometer and a numerical value of the DC power meter in the solar power generation system, calculate an inverter loss based on difference in numerical values between the DC power meter and an AC power meter, calculate a system output coefficient, calculate a module temperature loss based on a rated output power of the solar cell array, a temperature coefficient of the solar cell array, a numerical value of the voltage-current measuring device, a numerical value of the actinometer, a numerical value of a thermometer and a numerical value of the AC power meter, and calculate a module loss based on the cable loss, the maximum power point tracking loss, the inverter loss, the system output coefficient and the module temperature loss, and the alarm and advice device is configured to issue at least one of alarm and advice based on a monitoring result obtained from the displaying of the cable loss, the maximum power point tracking loss, the inverter loss, the module temperature loss and the module loss.

17. (canceled)

18. A system for monitoring solar power generation according to claim 16, wherein the computing device is configured to calculate the cable loss based difference in numerical values between an array end DC power meter provided on a solar cell array end and an inverter end DC power meter provided on an inverter end or based on wire resistance of a DC line connecting the solar cell array and the inverter and a numerical value of the inverter end DC power meter.

19. A system for monitoring solar power generation according to claim 16, wherein the computing device is configured to calculate the maximum power point tracking loss based on difference in numerical values between an inverter end DC power meter provided on an inverter end and a voltage-current measuring device configured to measure a voltage-current value of the solar cell array.

20. A system for monitoring solar power generation according to claim 16, wherein the computing device is configured to calculate the inverter loss based on difference in numerical values between an inverter end DC power meter provided on an inverter end and an AC power meter provided on the inverter end.
